(19) United States
(12) Patent Application Publication
(10) Pub. No.: US 2013/0047045 A1
(43) Pub. Date: Feb. 21, 2013

(54) ERROR INDICATOR FROM ECC DECODER

(71) Applicants: Xinde Hu, San Diego, CA (US); Anthony D. Weathers, San Diego, CA (US); Richard D. Barndt, San Diego, CA (US)

(72) Inventors: Xinde Hu, San Diego, CA (US); Anthony D. Weathers, San Diego, CA (US); Richard D. Barndt, San Diego, CA (US)

(73) Assignee: STEC, Inc., Santa Ana, CA (US)

(21) Appl. No.: 13/584,698

(22) Filed: Aug. 13, 2012

Related U.S. Application Data
(60) Provisional application No. 61/525,430, filed on Aug. 19, 2011.

(51) Int. Cl. H03M 13/05; G06F 11/00

(52) U.S. Cl. 714/708; 714/E11.004; 714/E11.032

(57) ABSTRACT

The subject disclosure provides a method for generating a read-level error signal, comprising, correcting a plurality of bits read from a flash memory, determining a first error rate of a first error type corrected in the bits and determining a second error rate of a second error type corrected in the bits. In certain aspects, methods of the subject technology further provides steps for comparing the first error rate with the second error rate and generating a read-level error signal based on the comparison of the first error rate and the second error rate. A decoder and flash storage device are also provided.

This application claims the benefit of U.S. Provisional Application No. 61/525,430, filed Aug. 19, 2011, entitled “ERROR INDICATOR FROM ECC DECODER,” the entirety of which is incorporated herein by reference.

### BACKGROUND

The subject disclosure relates to flash memory devices, such as solid-state drives (SSDs) that use flash memory to store data.

Over time, the cells of a flash memory device will lose charge, which can cause the threshold voltage of flash memory cells to drop. The more program/erase cycles the device has experienced, as well as the greater duration of time that charge is stored, the more extreme the decline in the threshold voltage. As a result, the cell distributions, corresponding to various programming levels, begin to widen and/or shift over time, leading to an increase in raw bit errors for data read from the flash memory.

### SUMMARY

The subject disclosure provides a method for generating a read-level error signal, comprising, correcting a plurality of bits read from a flash memory, determining a first error rate of a first error type corrected in the bits and determining a second error rate of a second error type corrected in the bits. In certain aspects, methods of the subject technology further provides steps for comparing the first error rate with the second error rate and generating a read-level error signal based on the comparison of the first error rate and the second error rate.

In other implementations, the subject disclosure provides a decoder configured to generate a read-level error signal, the decoder configured to perform operations comprising, decoding a code word read from a flash memory, determining a number of bits corrected in the decoded code word, determining an error type for each corrected bit and generating a read-level error signal based on the determined number of corrected bits and the determined error types.

In further aspects, the subject disclosure provides a flash storage device comprising a flash memory array, a controller configured to store encoded bits in the flash memory array and to read encoded bits from the flash memory array and a decoder coupled to the flash memory array and the controller, wherein the decoder is configured to perform operations for decoding a plurality of encoded bits read from the flash memory array, to generate a plurality of decoded bits and to determine a first error rate and a second error rate based on the decoding of the encoded bits. In certain aspects, the decoder is further configured to perform operations for, calculating an error bias based the first error rate and the second error rate and providing, to the controller, a read-level error signal indicating a read-level error in the flash memory based on the calculated error bias.

It is understood that other configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### BRIEF DESCRIPTION OF THE DRAWINGS

FIG. 1 is a block diagram illustrating components of a flash memory device, according to one aspect of the subject technology.

FIG. 2 is a graph illustrating an example of cell distributions and a read level for a LSB page read in a flash memory device, according to some aspects of the subject technology.

FIG. 3 is a graph illustrating an example of cell distributions and a high-read level for a LSB page read in a flash memory device, according to some aspects of the subject technology.

FIG. 4 is a graph illustrating an example of cell distributions and a low-read level for a LSB page read in a flash memory device, according to some aspects of the subject technology.

FIG. 5 illustrates an example of a method for generating a read-level error signal, according to some aspects of the subject technology.

FIG. 6A graphically illustrates an example of a read-level error indicator signal as a function of read level offset, for a low program/erase cycle count and no retention, according to some aspects of the disclosure.

FIG. 6B graphically illustrates an example of a read-level error indicator signal as a function of read level offset, for a low program/erase cycle count and a three hour retention, according to some aspects of the disclosure.

FIG. 7A graphically illustrates an example of a read-level error indicator signal as a function of read level offset, for a medium program/erase cycle count and no retention, according to some aspects of the disclosure.

FIG. 7B graphically illustrates an example of a read-level error indicator signal as a function of read level offset, for a medium program/erase cycle count and a three hour retention, according to some aspects of the disclosure.

FIG. 8A graphically illustrates an example of a read-level error indicator signal as a function of read level offset, for a high program/erase cycle count and no retention, according to some aspects of the disclosure.

FIG. 8B graphically illustrates an example of a read-level error indicator signal as a function of read level offset, for a high program/erase cycle count and a three hour retention, according to some aspects of the disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, it will be apparent to those skilled in the art that the subject technology may be practiced without these specific details. In some instances, well-known structures and components are shown in block diagram form in order to avoid obscuring the concepts of the subject technology. Like components are labeled with identical element numbers for ease of understanding.

Although flash memory cells can be adversely affected by high program/erase cycle counts and extended data storage durations, a significant portion of raw bit errors may also be caused by the misplacement of one or more read levels used to read the flash memory (e.g., due to shifts in programming level distributions caused by high program/erase cycle counts).

The subject technology provides a way to generate a read-level error signal based on a number and a type of raw bit errors occurring for data read from a flash memory. More specifically, the subject technology provides methods and systems for determining different types of read errors, and for producing a read-level error signal indicating a direction and degree of read level offset, for one or more LSB page read operations.

Implementations of the subject technology can be used to determine whether a read level is set too high, or is set too low. In certain aspects, this determination is made by calculating a first error type, based on a number of cells that were programmed having a logical value of ‘0’ and incorrectly read as logical ‘1.’ The determination can also involve the calculation of a second error type, based on a number of cells that were programmed having a logical value of ‘1’ and incorrectly read as logical ‘0.’ As will be described in further detail below, by comparing the first error type and the second error type, a read-level error indicator signal can be generated. In some implementations, the read-level error indicator can be used to trigger an adjustment of a read-level used for reading data from one or more LSB and/or MSB pages. Furthermore, in certain aspects, the read-level error indicator signal can be used to indicate a direction in which a read level should be adjusted and/or can be used to select an appropriate amount (e.g., a voltage amount) with which to adjust the read level.

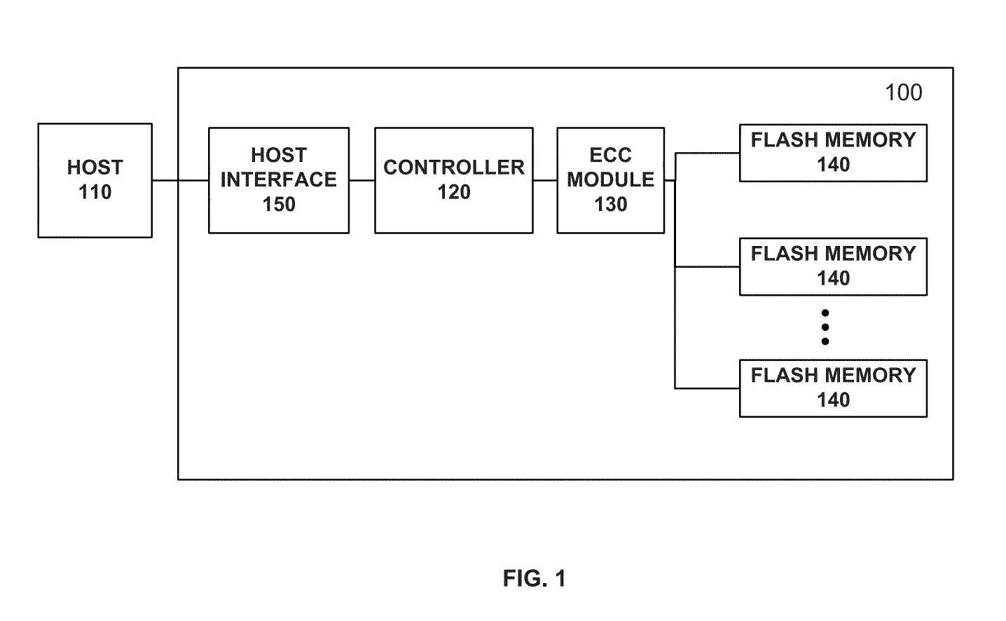

FIG. 1 is a block diagram illustrating an example of various components of a flash memory device 100. As depicted in FIG. 1, a host 110 is coupled to the flash memory device 100 that includes a host interface 150, a controller 120, ECC module 130 and a flash memory array 140. Depending on implementation, the elements of the flash memory device 100 can be integrated into a single chip or implemented in two or more discrete components.

The controller 120 can be implemented with a general-purpose microprocessor, a microcontroller, a digital signal processor (DSP), an application specific integrated circuit (ASIC), a field programmable gate array (FPGA), a programmable logic device (PLD), a controller, a state machine, gated logic, discrete hardware components, or a combination of the foregoing. One or more sequences of instructions can be stored as firmware on a ROM within the controller 120. One or more sequences of instructions can also be software stored and read from another storage medium, such as the flash memory array 140, or received from a host device (e.g., the host 110) via a host interface 150. ROM, storage mediums, and flash memory arrays represent examples of machine or computer readable media on which instructions/code executable by the controller 120 may be stored. As used herein, machine or computer readable media generally refers to any medium or media that can be used to provide instructions to the controller 120, including both volatile media, such as dynamic memory used for storage media or for buffers within the controller 120, and non-volatile media, such as electronic media, optical media and magnetic media.

The host interface 150 can be configured to implement a standard interface, such as Serial-Attached SCSI (SAS), Fiber Channel interface, PCI Express (PCIe), SATA, USB, and the like. The host interface 150 can be configured to implement only one interface. Alternatively, the host interface 150 may be configured to implement multiple interfaces, which are individually selectable using a configuration parameter selected by a user or programmed at the time of assembly. The host interface 150 can include one or more buffers for buffering transmissions between host device 110 and controller 120. A host device (e.g., the host 110) may be any device configured to be coupled to the data storage system and to store data in data storage system. In some examples, the host device may be a computing system such as a personal computer, a server, a workstation, a laptop computer, PDA, smart phone, and the like. Alternatively, the host device may be an electronic device such as a digital camera, a digital audio player, a digital video recorder or the like.

The flash memory array 140 represents non-volatile memory devices for storing data. By way of example, the flash memory array 140 can comprise a single-level cell (SLC) memory, a multi-level cell (MLC) memory or a three-level cell (TLC) memory device. In some aspects, the flash memory array 140 may comprise one or more hybrid memory devices that can function in one or more of a SLC, MLC or TLC mode.

Each component of the flash memory array 140 can include a single flash memory device or chip, or can include multiple flash memory devices or chips arranged in multiple channels, as depicted in FIG. 1. However, the flash memory is not limited to any particular capacity or configuration. For example, the number of cell states, the number of physical blocks, the number of physical pages per physical block, the number of sectors per physical page, and the size of the sectors may vary within the scope of the subject technology.

Additionally, one or more components of the flash memory array 140 can contain one or more registers (not shown) for storing data used to control various memory management operations. For example, the registers can comprise data for setting program verify levels, read levels, read operations and/or write operations, etc. In certain aspects, the flash memory array 140 can be configured to allow the one or more registers to be modified (e.g., via the controller 120) in order to adjust read levels for the one or more components (chips) of the flash memory array 140. By programming and/or re-programming one or more registers associated with the flash memory array 140, the controller 120 can change properties, such as read levels, of one or more chips of the flash memory array 140.

The ECC module 130 represents one or more components configured to generate code words to be stored in the flash memory array from data received from a host and to decode code words read from the flash memory array before sending the decoded data to the host. The ECC module 130 is not limited to any particular code. For example, the ECC module 130 may be configured to use BCH codes or LDPC codes to encode the data before storing in the flash memory array and to decode the data and correct bit errors when reading from the flash memory array 140. In other aspects, different ECC solutions may be used without departing from the scope of the subject technology.

As noted above, in some flash devices, raw bit errors can be caused by the incorrect placement of read levels. Accordingly, it would be useful to provide an error signal that is indicative of a degree and direction in which a read level is offset from its optimal location (e.g., its optimal voltage level).

In some implementations, the ECC module 130 is used to determine a first error rate of a first error type and a second error rate of a second error type, based on bits that are corrected by the ECC module 130. For example, after bits of an encoded code word are processed (i.e., decoded) by ECC module 130, the error-corrected code word is compared to the encoded code word to determine total numbers of errors of the first error type and the second error type.

In certain aspects, the first error type corresponds with one or more bits programmed with a logical value of ‘0,’ incorrectly read from the flash memory as having a logical value of ‘1.’ Whereas, the second error type corresponds with one or more bits programmed with a logical value of ‘1,’ incorrectly read from the flash memory as having a logical value of ‘0.’ The first type of errors is referred to as the “zError,” and the second type of errors is referred to as the “oError.”

A comparison of the oError and zError can be used to generate a read-level error signal. The read-level error signal can comprise a value (e.g., a magnitude) and a sign. The value of the read-level error may be indicative of a degree or severity of raw bit errors for data being read from flash e.g., raw bit errors caused by misplaced read-levels. The sign of the read-level error signal may indicate a direction of read level offset for the read levels. Thus, the value and sign of the read-level error signal can be used to indicate the degree and direction in which one or more read levels are offset from their optimal location.

By way of example, the read-level error signal can comprise a plurality of bits, for example three bits, indicating a value (e.g., in a range of 0 to 3) and a sign (+/−), corresponding to the degree and direction by which the read-level is offset (e.g., from its optimal value). In some implementations, the value and the sign of the read-level error can be used to adjust the read-level. For example, the value and the sign of the read-level error signal can be mapped to an adjustment amount (e.g., a voltage amount by which the read level should be moved) and a direction (e.g., an indication as to whether the read level should be incremented or decremented). Thus, in certain aspects, the read-level error signal can be used to provide the controller 120 with an indication as to how one or more registers of the flash memory 140 should be programmed/re-programmed in order to adjust a read-level for one or more LSB or MSB page read operations.

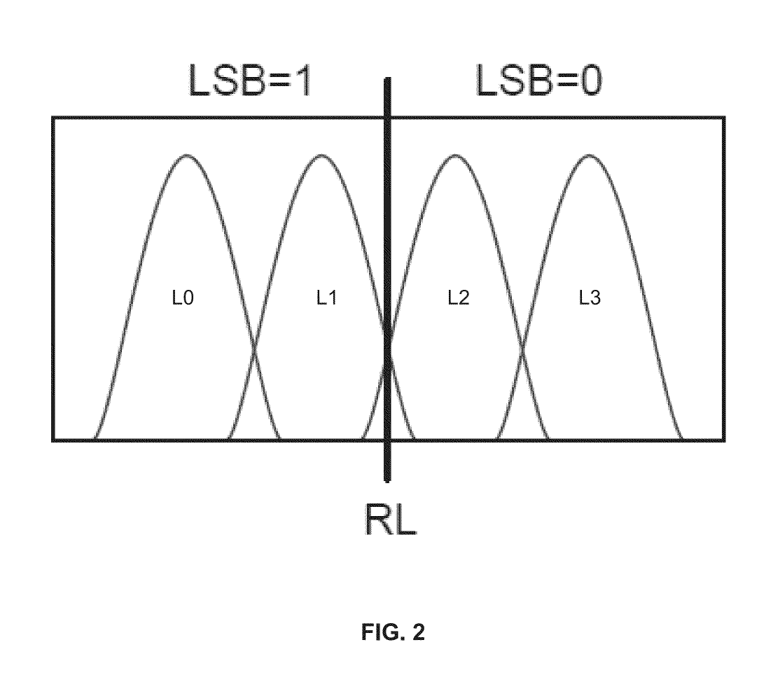

FIG. 2 depicts a graph illustrating cell distributions in a MLC flash memory together with the position of a read-level (RL) used to read a LSB page. As illustrated, each of the cell distributions corresponds with a programming level (e.g., L0, L1, L2 or L3) and the upper two distributions correspond to an LSB value of 0, whereas the lower two distributions correspond to an LSB value of 1. The illustration of FIG. 2 provides an example of a RL position that is optimally placed between LSB=0 and LSB=1, so as to minimize the raw bit error rate for cells read from the LSB page. In this configuration, the probability of erroneously reading cells as being below RL (e.g., in LSB 1), will be approximately equal to the probability of erroneously reading cells as above RL (e.g., in LSB 0). In other words, as bits (e.g., one or more code words) are decoded by the ECC module, the zError and the oError will be approximately equal.

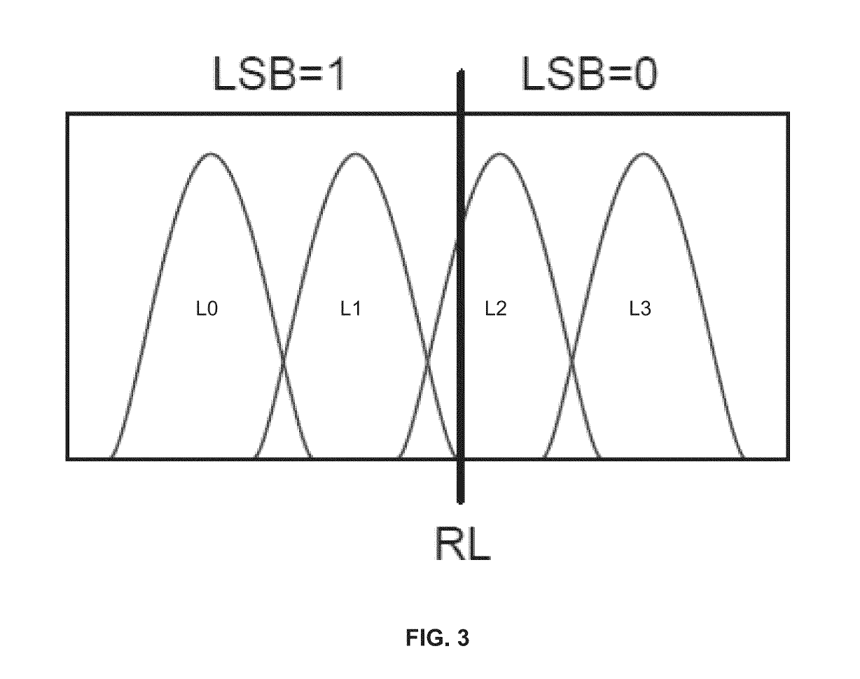

FIG. 3 depicts a graph illustrating cell distributions in a MLC flash memory, similar to that of FIG. 2. However, in the example of FIG. 3, the RL used to read the LSB page is placed too high. As a result, there is a greater probability for cells from the L2 programming level to be incorrectly read below RL (e.g., incorrectly read as belonging to LSB 1), leading to an increase in the zError as compared to the oError.

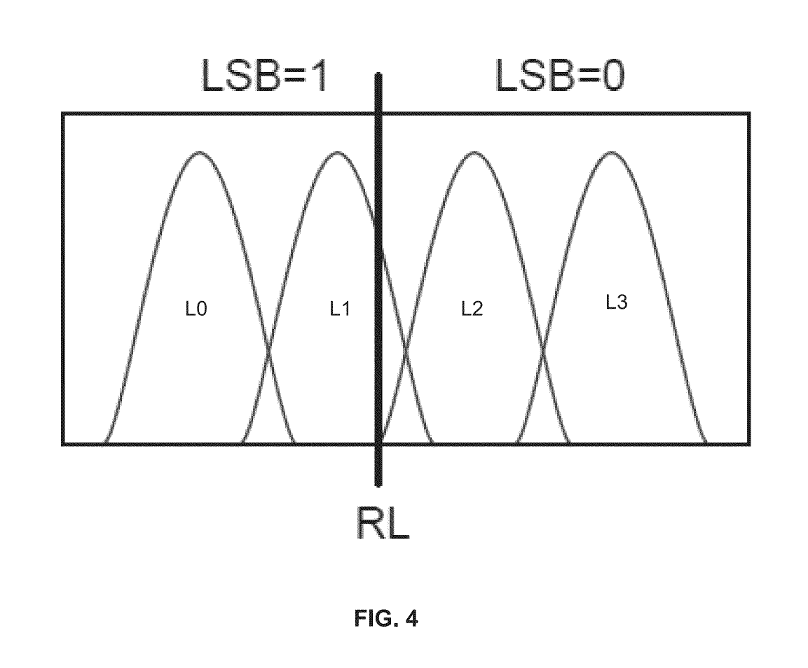

FIG. 4 depicts a graph illustrating cell distributions in a MLC flash memory, similar to that of FIG. 3. However, in the example of FIG. 4, the RL used to read the LSB page is placed too low. Consequently a greater number of cells belonging to the L1 programming level will be incorrectly read above RL (e.g., incorrectly read as belonging to LSB 0), leading to an increase in the oError compared to the zError.

In certain aspects, the subject technology uses measures of oError and zError to generate a read-level error signal. The resulting read-level error signal can then be used (e.g., by the controller) to adjust/readjust a read level (RL). Depending on implementation, the read-level error signal can indicate whether a read level should be adjusted, and if so, in what direction the read level should be adjusted (e.g., by either increasing or decreasing the read level voltage). In certain aspects, the read-level error signal can further be used to determine an amount (e.g., a value) by which the read level should be adjusted.

In certain implementations, a read-level error signal is based on a comparison of the oError and the zError. For example, if the zError is greater than the oError by a threshold amount, a read-level error signal indicating that one or more read levels need to be adjusted down may be generated. Alternatively, if the oError is greater than the zError by a threshold amount, a read-level error signal indicating that the one or more read levels need to be adjusted up may be generated. The threshold amounts necessary to adjust a particular RL (either up or down) can vary with implementation and may be set based on simulations and/or experimental results obtained for different types of flash memory, under various conditions, that may be used in the flash memory device.

In certain implementations, rather than simply comparing the difference between the oError and the zError, these two values may be normalized to create a read-level error signal:

$$γ = \frac{oError - zError}{zError + oError} \qquad ( 1 )$$

Depending on the desired implementation, other formulas can be used. After the read level error signal has been generated, the read-level error signal can then be provided to the controller (e.g., the controller 120) that can use the sign and value of the read-level error signal to determine whether one or more read levels (e.g., one or more read levels of the flash memory array 140) should be adjusted, and in which direction the adjustment should be made.

In certain implementations, a read-level error signal may not be generated until a statistically significant number of bits have been corrected e.g., by the ECC module 130. For example, it may be a requirement that the ECC module 130 be used to decode the entirety of one or more code words before a read-level error signal is generated. By way of further example, a minimum of 25 bit errors or 50 bits from an 8 kbit page may need to be corrected by the ECC module before oError and zError signals can be used to generate a read-level signal; however, depending on implementation, other values for this minimum can be used.

In some implementations, running counts of the oError and zError may be tracked, for example, as the ECC module continues to decode subsequent code words. Accordingly, the read-level error signal may be generated in response to the oError and zError measured across one or more decoded code words.

To ensure the viability of the oError and zError measurements, a number of conditions may be required. For example, it may be required that the data read from the flash memory be comprised of a substantially equal number of logical ‘1’ and logical ‘0’ values. In certain aspects, a statistical balance for data stored to the flash memory can be accomplished using a scrambler or encryption engine so that (independent of information content), an approximately equal number of logical ‘1’ and logical ‘0’ values get stored in the flash memory.

The subject technology is not limited to any particular process for adjusting read levels. For example, the controller can utilize a maintenance process (e.g., as a background operation) to determine how much to adjust the read levels based on the read-level error signal. Alternatively, the controller can be configured to simply increment (or decrement) one or more read levels by a set amount if the read-level error indicator signal indicates that the one or more read levels should be adjusted.

Furthermore, in some implementations, the read-level error signal based on data read from one or more MSB pages on a particular chip may be used to adjust one or more read levels (e.g., read levels corresponding to different programming levels) for one or more different flash chips, for example, one or more flash memory devices 140.

Although the read-level error signal can be generated based on oError and zError information obtained from one or more LSB page read operations, the read-level error signal can also be used to adjust MSP read levels. For example, in some implementations, it may be inferred that a drift in a read level for a MSB page is indicative of a (similar) drift in a read level for one or more MSB pages. Accordingly, comparisons of oError and zError can be used to determine a direction (sign) and value (magnitude) for adjustments to one or more MSB read levels for one or more flash chips.

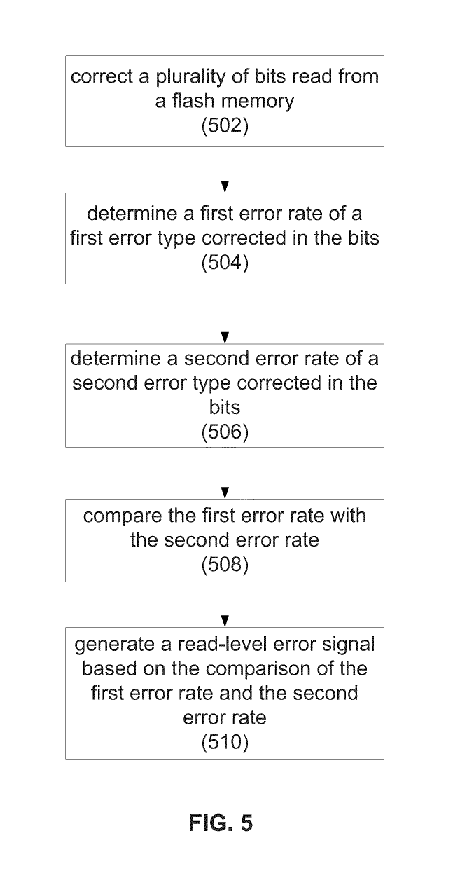

FIG. 5 illustrates an example of a method 500 for generating a read-level error signal. The method 500 begins with step 502 in which a plurality of bits read from the flash memory are corrected. As discussed above, the plurality of bits can be corrected (e.g., decoded) using an ECC module, such as the ECC module 130, illustrated in FIG. 1.

The plurality of bits read from the flash memory can comprise an equal (or substantially equal) number of logical ‘1’ and logical ‘0’ values. Depending on implementation, the frequency of logical ‘1’ and logical ‘0’ values read from the flash memory can be ensured using a scrambler or encryption engine, as discussed above.

In step 504, a first error rate, of a first error type, corrected in the bits is determined. In certain aspects, after the plurality of bits (e.g., one or more code words) is decoded (e.g., using an ECC module), a number of errors of the first error type will be counted. By way of example, after the plurality of bits have undergone error code correction (e.g., decoding) the number of bits programmed as logical ‘0’ and incorrectly read as logical ‘1,’ will be determined. This value is designated as the zError.

In step 506, a second error rate of a second error type corrected in the bits is determined. For example, after the plurality of bits is decided, a number of errors of the second error type will be counted by determining the number of bits that were programmed logical ‘1’ and incorrectly read as logical ‘0,’ (e.g., the oError).

Subsequently, in step 508, the first error rate is compared with the second error rate. Although, any number of metrics can be used to compare the zError and the oError, in certain implementations, the error rate comparison will be normalized according to Equation (1), shown above.

In step 510, a read-level error signal will be generated based on the comparison of the first error rate and the second error rate, as determined in steps 506 and 508, respectively. In some implementations, the read-level error signal will only be generated after a threshold number of bits read from the flash memory have been corrected. In other implementations, the read-level error signal may only be generated if a threshold difference between the zError and oError is observed.

As discussed above, the read-level error signal can be used to adjust one or more read levels for one or more MSB and/or LSB page reads, on one or more flash chips. The read-level error signal can comprise a sign and a value (magnitude) used to indicate the direction and size of adjustment to be made to one or more read levels. In practice, the adjustment of one or more read levels can be performed by a controller (e.g., the controller 120 as discussed above with respect to FIG. 1).

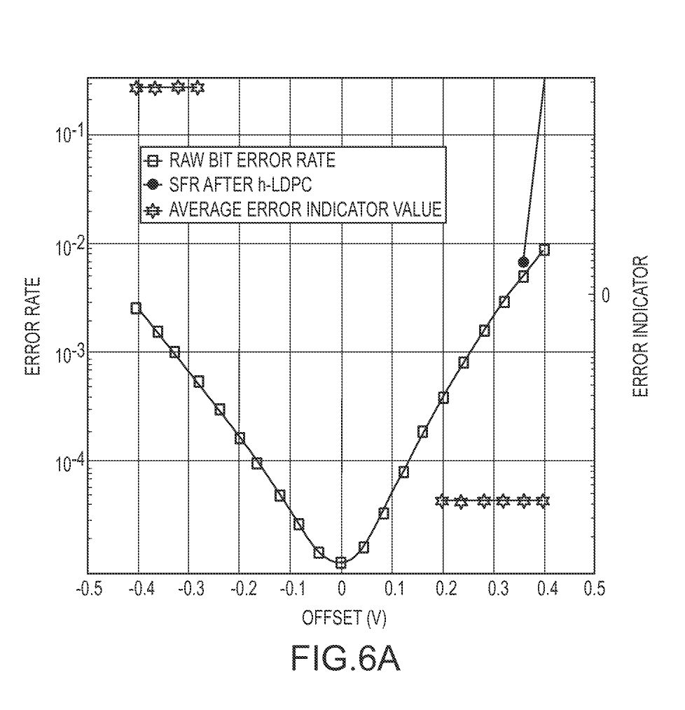

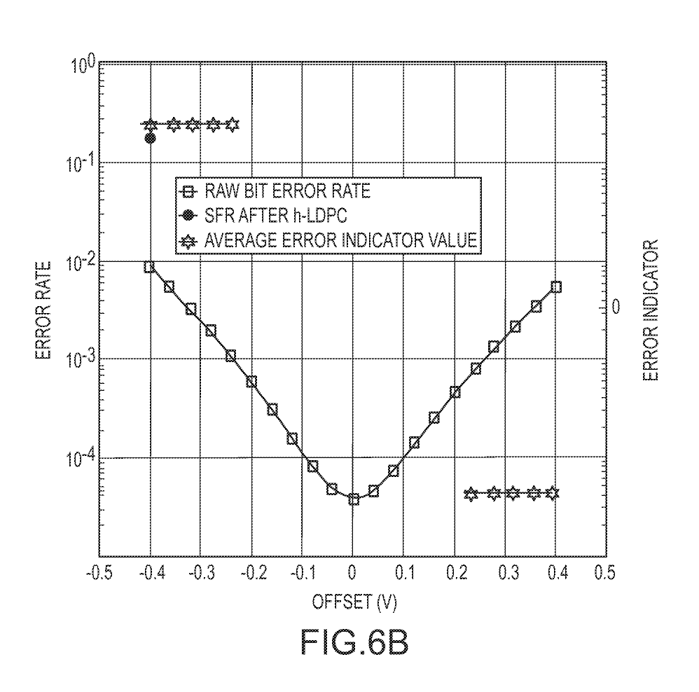

FIGS. 6A and 6B graphically illustrate examples of a read-level error indicator signal as a function of read level offset for low program/erase (P/E) cycle counts (e.g., a cycle count of 10 k). Specifically, FIG. 6A illustrates a case with zero retention, and FIG. 6B illustrates a case with a retention of three hours. As illustrated in the graphs of FIGS. 6A and 6B, although the read-level error indicator signal is only generated when the offset exceeds certain levels, at a low number P/E cycles there are so few errors that decoding can be performed on all code words.

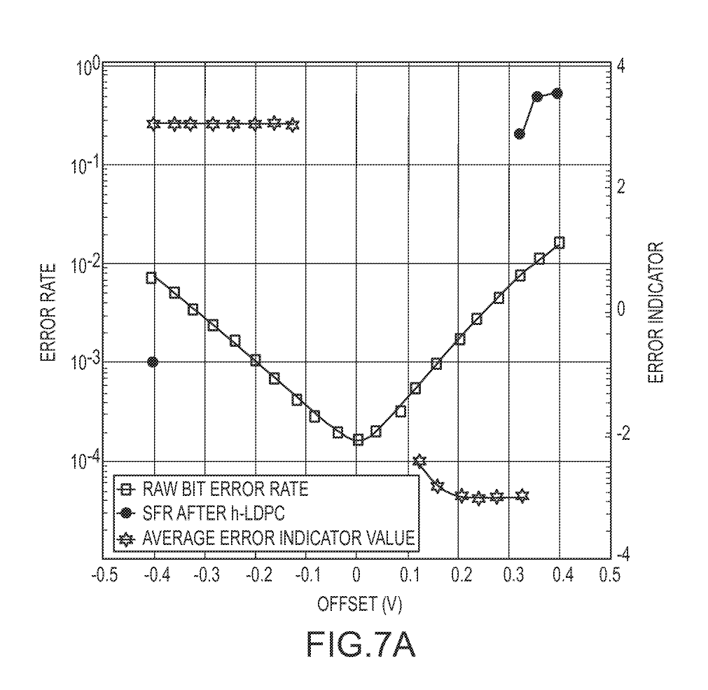

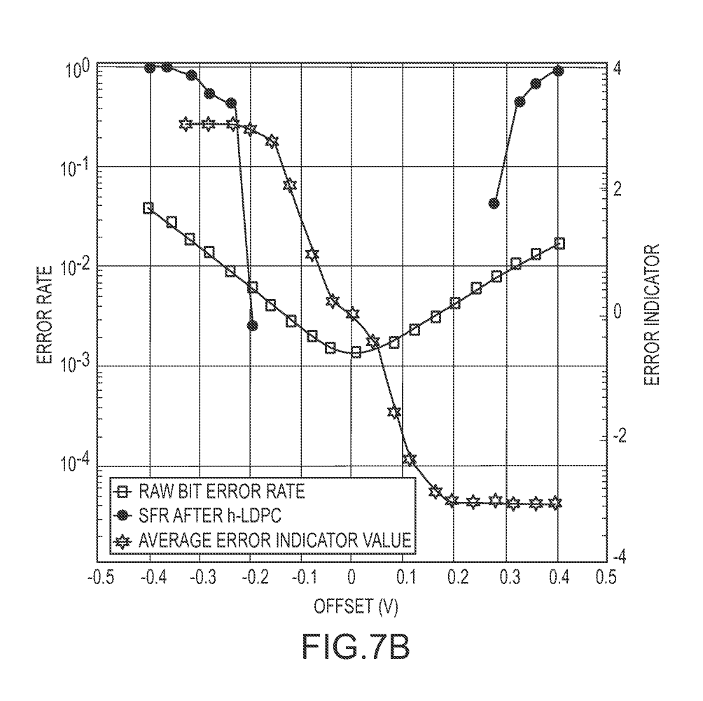

FIGS. 7A and 7B graphically illustrate examples of a read-level error indicator signal as a function of read level offset for a medium program/erase cycle count (e.g., for a cycle count of 40 k). Specifically, FIG. 7A illustrates a case with zero retention and FIG. 7B illustrates a case with a retention of three hours.

As illustrated in the example of FIG. 7A (without retention), the sector fail rate (SFR) increases for offset voltages greater than about 300 mV.

In the example of FIG. 7B (with retention), the overall SFR increases at a lower offset voltage (e.g., greater than about 200 mV). As illustrated by FIG. 7B, the read-level error indicator closely corresponds with the read level offset.

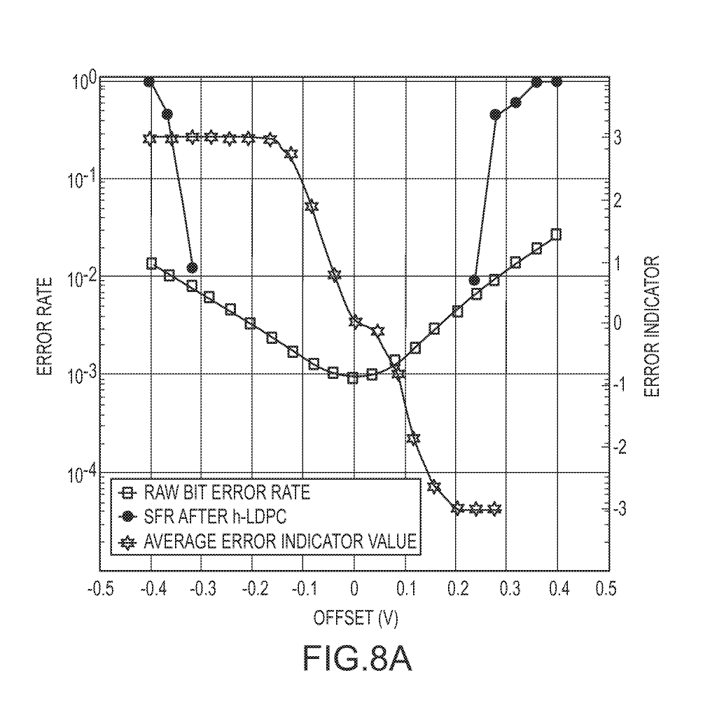

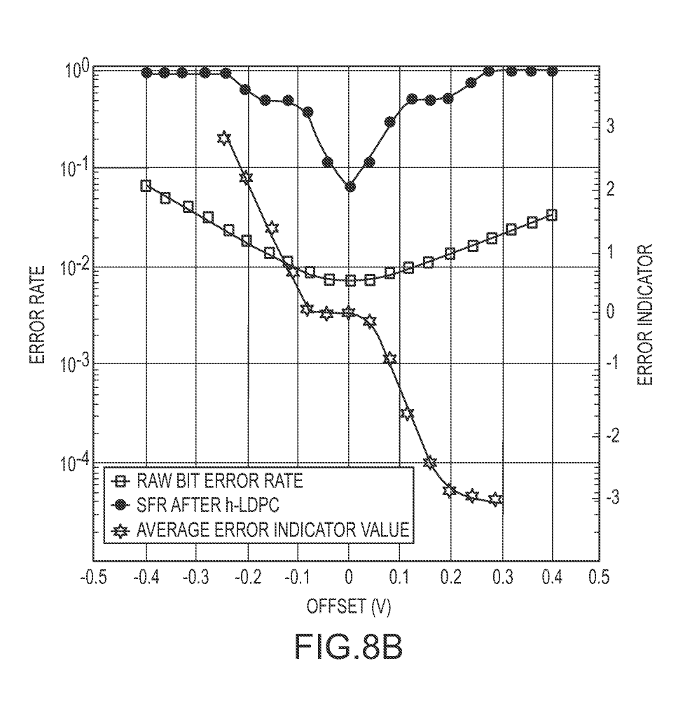

FIGS. 8A and 8B graphically illustrate examples of a read-level error indicator signal as a function of read level offset for high program/erase cycle counts (e.g., for a cycle count of 70 k). Specifically, FIG. 8A illustrates a case with zero retention and FIG. 8B illustrates a case with a retention of three hours.

As illustrated in the example of FIG. 8A (without retention), the probability of data recovery for offsets of less than about 300 mV is quite high and thus little feedback (e.g., from the read-level error indicator) is needed.

In the example of FIG. 8B (with retention), the overall sector fail rate (SFR) increases with the read level offset. As illustrated by FIG. 8B, the read-level error indicator shares a near linear relationship with the corresponding SFR.

Those of skill in the art would appreciate that the various illustrative blocks, modules, elements, components, methods, and algorithms described herein may be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

It is understood that the specific order or hierarchy of steps in the processes disclosed is an illustration of exemplary approaches. Based upon design preferences, it is understood that the specific order or hierarchy of steps in the processes may be rearranged. Some of the steps may be performed simultaneously. The accompanying method claims present elements of the various steps in a sample order, and are not meant to be limited to the specific order or hierarchy presented.

The previous description is provided to enable any person skilled in the art to practice the various aspects described herein. The previous description provides various examples of the subject technology, and the subject technology is not limited to these examples. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the invention.

The predicate words “configured to”, “operable to”, and “programmed to” do not imply any particular tangible or intangible modification of a subject, but, rather, are intended to be used interchangeably. For example, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

A phrase such as an “aspect” does not imply that such aspect is essential to the subject technology or that such aspect applies to all configurations of the subject technology. A disclosure relating to an aspect may apply to all configurations, or one or more configurations. An aspect may provide one or more examples. A phrase such as an aspect may refer to one or more aspects and vice versa. A phrase such as an “embodiment” does not imply that such embodiment is essential to the subject technology or that such embodiment applies to all configurations of the subject technology. A disclosure relating to an embodiment may apply to all embodiments, or one or more embodiments. An embodiment may provide one or more examples. A phrase such as an “embodiment” may refer to one or more embodiments and vice versa. A phrase such as a “configuration” does not imply that such configuration is essential to the subject technology or that such configuration applies to all configurations of the subject technology. A disclosure relating to a configuration may apply to all configurations, or one or more configurations. A configuration may provide one or more examples. A phrase such as a “configuration” may refer to one or more configurations and vice versa.

The word “exemplary” is used herein to mean “serving as an example or illustration.” Any aspect or design described herein as “exemplary” is not necessarily to be construed as preferred or advantageous over other aspects or designs.

What is claimed is:

1. A method for generating a read-level error signal, comprising:
correcting a plurality of bits read from a flash memory;
determining a first error rate of a first error type corrected in the bits;
determining a second error rate of a second error type corrected in the bits;
comparing the first error rate with the second error rate; and
generating a read-level error signal based on the comparison of the first error rate and the second error rate.

2. The method of claim 1, wherein the first error type is a programmed logical ‘0’ incorrectly read as a logical ‘1.’

3. The method of claim 1, wherein the second error type is a programmed logical ‘1’ incorrectly read as a logical ‘0.’

4. The method of claim 1, further comprising:
comparing a number of corrected bits with a threshold, wherein the read-level error signal is generated if the number of corrected bits exceeds a threshold.

5. The method of claim 1, wherein the read-level error signal comprises a sign and a value, wherein the sign indicates a direction of the read-level error and the value indicates a degree of the read-level error.

6. The method of claim 1, wherein the plurality of bits are read from a LSB page in the flash memory.

7. The method of claim 1, wherein a number of the plurality of bits read from the flash memory having a logical value of ‘0’ is equal to a number of the plurality of bits read from the flash memory having a logical value of ‘1.’

8. The method of claim 1, further comprising:
adjusting a read level of the flash memory based on the read-level error signal.

9. A decoder configured to generate a read-level error signal, the decoder configured to perform operations comprising:
decoding a code word read from a flash memory;
determining a number of bits corrected in the decoded code word;
determining an error type for each corrected bit; and
generating a read-level error signal based on the determined number of corrected bits and the determined error types.

10. The decoder of claim 9, further comprising:
comparing a number of corrected bits with a threshold, wherein the read-level error signal is generated if the number of corrected bits exceeds a threshold.

11. The decoder of claim 9, wherein the read-level error signal comprises a sign and a value, wherein the sign indicates a direction of the read-level error and the value indicates a degree of the read-level error.

12. The decoder of claim 9, wherein the code word is read from a LSB page in the flash memory.

13. The decoder of claim 9, wherein a number of code word bits read from the flash memory having a logical value of ‘0’ is equal to a number of code word bits read from the flash memory having a logical value of ‘1.’

14. A flash storage device, comprising:
a flash memory array;
a controller configured to store encoded bits in the flash memory array and to read encoded bits from the flash memory array; and
a decoder coupled to the flash memory array and the controller, wherein the decoder is configured to perform operations for:
decoding a plurality of encoded bits, read from the flash memory array, to generate a plurality of decoded bits;
determining a first error rate and a second error rate based on the decoding of the encoded bits;
calculating an error bias based the first error rate and the second error rate; and
providing, to the controller, a read-level error signal indicating a read-level error in the flash memory based on the calculated error bias.

15. The flash storage device of claim 14, wherein the first error rate is based on a number of bits programmed as logical ‘0’ and incorrectly read as a logical ‘1.’

16. The flash storage device of claim 14, wherein the first error rate is based on a number of bits programmed as logical ‘1’ and incorrectly read as a logical ‘0.’

17. The flash storage device of claim 14, wherein providing the read-level error signal is based on whether a difference between the first error rate and the second error rate exceeds a threshold.

18. The flash storage device of claim 14, wherein the read-level error signal comprises a sign and a value, wherein the sign indicates a direction of the read-level error and the value indicates a degree of the read-level error.

19. The flash storage device of claim 14, wherein the plurality of encoded bits are read from a LSB page in the flash memory array.

20. The flash storage device of claim 14, wherein a number of encoded bits read from the flash memory array having a logical value of ‘0’ is equal to a number of encoded bits read from the flash memory having a logical value of ‘1.’

21. The flash storage device of claim 14, wherein the error bias is calculated based on a difference between a proportion of total errors for the first error rate and a proportion of total errors for the second error rate.
